(19) United States
(12) Patent Application Publication
(10) Pub. No.: US 2023/0260760 A1
(43) Pub. Date: Aug. 17, 2023

(54) SUBSTRATE PROCESSING APPARATUS

(71) Applicant: Tokyo Electron Limited, Tokyo (JP)

(72) Inventor: Ibuki HAYASHI, Oshu City (JP)

(21) Appl. No.: 18/106,036

(22) Filed: Feb. 6, 2023

(30) Foreign Application Priority Data
Feb. 14, 2022 (JP) 2022-020521

(51) Int. Cl. H01J 37/32; C23C 16/458; C23C 16/455; C23C 16/50

(52) U.S. Cl. CPC H01J 37/32449; H01J 37/32513; C23C 16/4584; C23C 16/45565; C23C 16/50; H01J 2237/201; H01J 2237/20214; H01J 2237/24578; H01J 2237/332

(57) ABSTRACT

A substrate processing apparatus includes a vacuum container, a placing part provided inside the vacuum container and having a placing surface on which a substrate is placed, and a ceiling member provided above the placing part. The ceiling member includes a fixed member fixed to the vacuum container, a movable member attached to the fixed member and having a first facing surface facing the placing surface, a spacer sandwiched between the fixed member and the movable member, a first seal member provided between the fixed member and the spacer, a second seal member provided between the movable member and the spacer, and a plurality of adjustment bolts screwed into the fixed member through the movable member.

### CROSS-REFERENCE TO RELATED APPLICATION

This application is based upon and claims the benefit of priority from Japanese Patent Application No. 2022-020521, filed on Feb. 14, 2022, the entire contents of which are incorporated herein by reference.

### TECHNICAL FIELD

The present disclosure relates to a substrate processing apparatus.

### BACKGROUND

Techniques for adjusting a gap, an inclination, and flatness of a faceplate of a shower head module with respect to an upper surface of a substrate pedestal module adjacent to a faceplate of a substrate processing apparatus by means of a shower head tilt adjustment mechanism are known (see, e.g., Patent Document 1).

### PRIOR ART DOCUMENTS

### Patent Document

[Patent Document 1] Japanese laid-open publication No. 2020-529126

### SUMMARY

According to one embodiment of the present disclosure, there is provided a substrate processing apparatus including a vacuum container, a placing part provided inside the vacuum container and having a placing surface on which a substrate is placed, and a ceiling member provided above the placing part, wherein the ceiling member includes a fixed member fixed to the vacuum container, a movable member attached to the fixed member and having a first facing surface facing the placing surface, a spacer sandwiched between the fixed member and the movable member, a first seal member provided between the fixed member and the spacer, a second seal member provided between the movable member and the spacer, and a plurality of adjustment bolts screwed into the fixed member through the movable member.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic cross-sectional view showing a substrate processing apparatus according to an embodiment.

FIG. 2 is a schematic perspective view showing an internal configuration of a vacuum container of the substrate processing apparatus according to the embodiment.

FIG. 3 is a schematic plan view showing an internal configuration of the vacuum container of the substrate processing apparatus according to the embodiment.

FIG. 4 is another schematic cross-sectional view of the substrate processing apparatus according to the embodiment.

FIG. 5 is another schematic cross-sectional view of the substrate processing apparatus according to the embodiment.

FIG. 6 is a schematic perspective view showing a shower head according to an embodiment.

FIG. 7 is a schematic plan view showing the shower head according to the embodiment.

FIG. 8 is a schematic cross-sectional view showing the shower head according to the embodiment.

FIG. 9 is a view showing ae configuration of a lower surface of a bottom plate of the shower head according to the embodiment.

FIG. 10 is a schematic cross-sectional view showing a shower head according to a modification of the embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail not to unnecessarily obscure aspects of the various embodiments.

Non-limiting exemplary embodiments of the present disclosure will now be described with reference to the accompanying drawings. Throughout the accompanying drawings, the same or corresponding members or parts are denoted by the same or corresponding reference numerals, and explanation thereof will not be repeated.

### [Substrate Processing Apparatus]

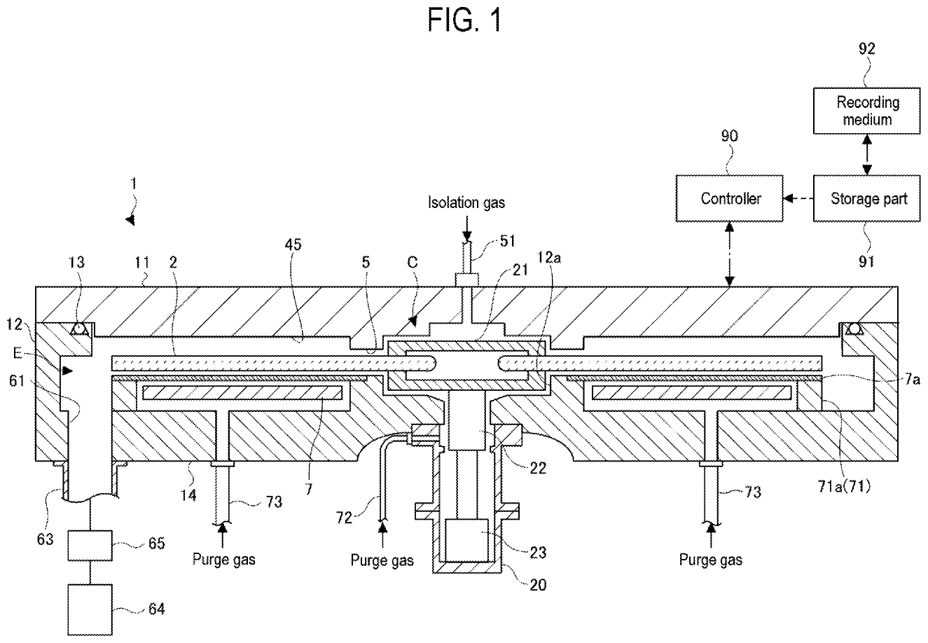

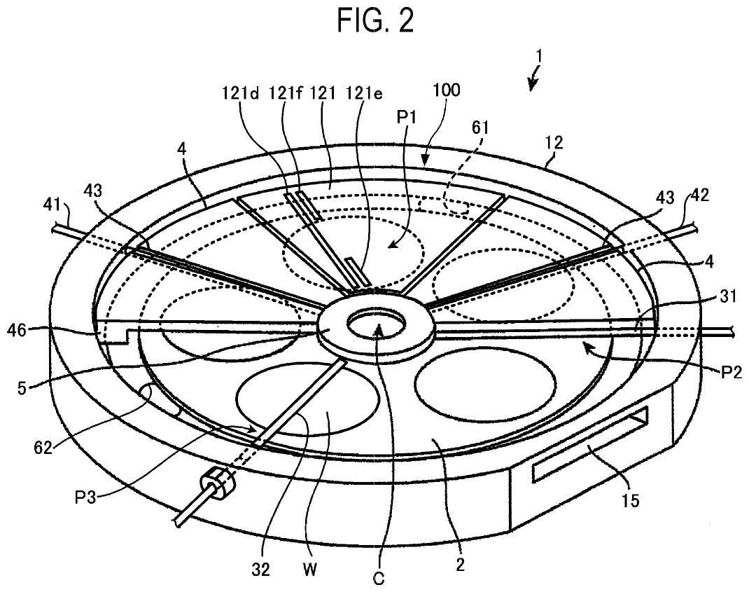

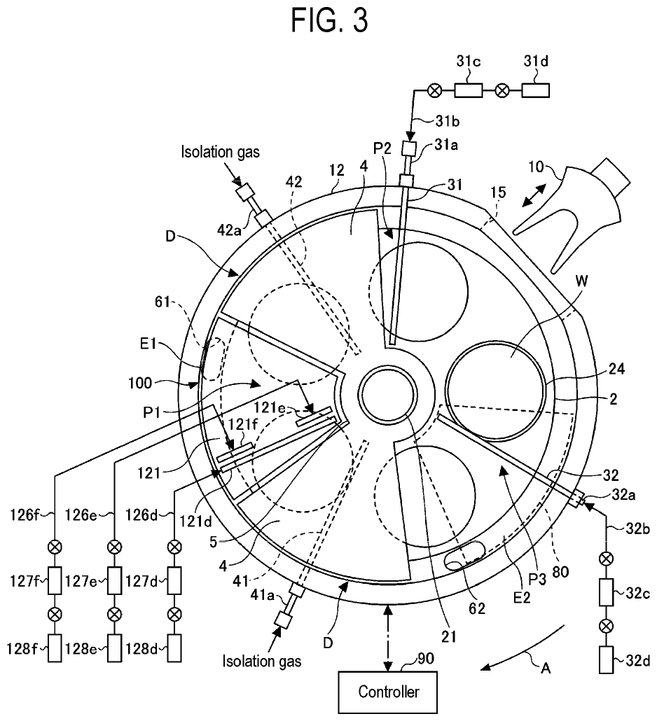

A substrate processing apparatus according to an embodiment will be described with reference to FIGS. 1 to 5. FIG. 1 is a schematic cross-sectional view showing a substrate processing apparatus according to an embodiment. FIGS. 2 and 3 are views for explaining an internal configuration of a vacuum container 1 of the substrate processing apparatus according to the embodiment. In FIGS. 2 and 3, a ceiling plate 11 is not shown for the sake of convenience of description.

The substrate processing apparatus according to the embodiment is configured with an apparatus that performs a film forming process on a plurality of substrates W at once. The substrate W is, for example, a semiconductor wafer. The substrate processing apparatus includes a vacuum container 1 and a rotary table 2.

The vacuum container 1 has a substantially circular shape in a plan view. The vacuum container 1 accommodates the substrate W therein. The vacuum container 1 is configured with a process chamber in which the substrate W is subjected to a process such as a film forming process. The vacuum container 1 includes a ceiling plate 11 and a container body 12. The ceiling plate 11 is provided at a position facing the upper surface of the rotary table 2. The ceiling plate 11 is configured to be detachable from the container body 12. A seal member 13 having an annular shape is provided on the periphery of the upper surface of the container body 12. The seal member 13 is, for example, an O-ring.

The rotary table 2 is rotatably provided inside the vacuum container 1. The rotary table 2 has its center of rotation at the center of the vacuum container 1. The rotary table 2 is fixed to substantially a cylindrical core portion 21 at its central portion. A driving part 23 is connected to the core portion 21 via a rotary shaft 22 extending in the vertical direction. The driving part 23 rotates the rotary table 2 around the vertical axis, for example clockwise, via the rotary shaft 22 and the core portion 21.

The rotary shaft 22 and the driving part 23 are housed in a case body 20. The case body 20 has a tubular shape. An upper flange of the case body 20 is air-tightly attached to the lower surface of the bottom 14 of the vacuum container 1.

A concave portion 24 is formed in the upper surface of the rotary table 2. The concave portion 24 has a circular shape in a plan view. The substrate W is placed in the concave portion 24. The concave portions 24 are provided at a plurality of locations, for example, five locations, along the direction of rotation. The concave portion 24 has an inner diameter slightly larger than the diameter of the substrate W. The concave portion 24 have a depth approximately equal to the thickness of the substrate W or greater than the thickness of the substrate W. As a result, when the substrate W is placed on the concave portion 24, the surface of the substrate W and the surface of a region of the rotary table 2 where the substrate W is not placed are at the same height, or the surface of the substrate W is lower than the surface of the rotary table 2. A plurality of through-holes, for example, three through-holes, are provided in the bottom surface of the concave portion 24. A lift pin (not shown) is inserted into each through-hole. The lift pin push up the substrate W from below to lift the substrate W.

Above the rotary table 2, a shower head 100, process gas nozzles 31 and 32, and isolation gas nozzles 41 and 42 are disposed spaced apart from each other in the rotational direction of the rotary table 2 indicated by an arrow A in FIG. 3. In the shown example, the process gas nozzle 32, the isolation gas nozzle 41, the shower head 100, the isolation gas nozzle 42, and the process gas nozzle 31 are arranged in this order in the rotational direction of the rotary table 2 from a transfer port 15 which will be described later. The process gas nozzle 32, the isolation gas nozzle 41, the shower head 100, the isolation gas nozzle 42, and the process gas nozzle 31 are each made of quartz.

The shower head 100 has a bottom plate 121. The bottom plate 121 is formed with a precursor gas supply 121d, a shaft side auxiliary gas supply 121e, and an outer auxiliary gas supply 121f. The precursor gas supply 121d, the shaft side auxiliary gas supply 121e, and the outer auxiliary gas supply 121f extend along the radial direction of the rotary table 2. A plurality of discharge holes (not shown) are formed in the bottom surface of each of the precursor gas supply 121d, the shaft side auxiliary gas supply 121e, and the outer auxiliary gas supply 121f to supply a precursor gas, a shaft side auxiliary gas, and an outer auxiliary gas along the radial direction of the rotary table 2, respectively. The precursor gas supply 121d extends along the radial direction of the rotary table 2 over the entire radius to cover the entire substrate W. The shaft side auxiliary gas supply 121e extends over only a region of the shaft side of the rotary table 2 by about ⅓ of the precursor gas supply 121d. The outer auxiliary gas supply 121f extends over only a region of the outer side of the rotary table 2 by about ⅓ of the precursor gas supply 121d.

The nozzles 31, 32, 41, and 42 are introduced into the vacuum container 1 from the outer peripheral surface of the vacuum container 1 by fixing gas introduction ports 31a, 32a, 41a, and 42a, which are the base ends of the nozzles 31, 32, 41, and 42, to the outer peripheral surface of the container body 12. The nozzles 31, 32, 41, and 42 are attached to extend horizontally with respect to the rotary table 2 along the radial direction of the container body 12.

The precursor gas supply 121d, the shaft side auxiliary gas supply 121e, and the outer auxiliary gas supply 121f are provided on the bottom plate 121. Therefore, the precursor gas, the shaft side auxiliary gas, and the outer auxiliary gas introduced into the shower head 100 are injected into the vacuum container 1 via the precursor gas supply 121d, the shaft side auxiliary gas supply 121e, and the outer auxiliary gas supply 121f, respectively.

The precursor gas supply 121d is connected to a precursor gas supply source 128d via a pipe 126d, a flow controller 127d, and the like. The shaft side auxiliary gas supply 121e is connected to a shaft side auxiliary gas supply source 128e via a pipe 126e, a flow controller 127e, and the like. The outer auxiliary gas supply 121f is connected to an outer auxiliary gas supply source 128f via a pipe 126f, a flow controller 127f, and the like. The precursor gas includes, for example, a silicon-containing gas such as an organic aminosilane gas, or a titanium-containing gas such as TiCl₄. The shaft side auxiliary gas and the outer auxiliary gas include, for example, a rare gas such as an argon gas, and an inert gas such as a nitrogen gas. The shaft side auxiliary gas and the outer auxiliary gas may include, for example, the same gas as the precursor gas. As for the shaft side auxiliary gas and the outer auxiliary gas, gases that are preferable for improving the in-plane uniformity, such as adjusting the film thickness, are appropriately selected according to the application and process.

The process gas nozzle 31 is connected to a reaction gas supply source 31d via a pipe 31b, a flow controller 31c, and the like. A reaction gas is a gas that reacts with the precursor gas to generate a reaction product. Examples of the reaction gas may include an oxygen-containing gas such as an ozone gas for the silicon-containing gas, a nitrogen-containing gas such as an ammonia gas for the titanium-containing gas, and the like.

The process gas nozzle 32 is connected to a modifying gas supply source 32d via a pipe 32b, a flow controller 32c, and the like. A modifying gas is a gas capable of generating plasma in order to improve the film quality of the generated reaction product, and in many cases, a gas having properties similar to those of the reaction gas is used as the modifying gas. Examples of the modifying gas may include an oxygen-containing gas such as an oxygen gas or an ozone gas for the silicon-containing gas, a nitrogen-containing gas such as an ammonia gas or a nitrogen gas for the titanium-containing gas, and the like.

The isolation gas nozzles 41 and 42 are both connected to an isolation gas supply source (not shown) via a pipe, a flow control valve (both not shown), and the like. A rare gas such as a helium gas or an argon gas, and an inert gas such as a nitrogen gas can be used as an isolation gas.

In the process gas nozzles 31 and 32, a plurality of discharge holes 33 opened toward the rotary table 2 are arranged along the lengthwise direction of the process gas nozzles 31 and 32 at intervals of, for example, 10 mm.

A region below the bottom plate 121 serves as a precursor gas supply region P1 in which the precursor gas is adsorbed on the substrate W. A region below the process gas nozzle 31 serves as a reaction gas supply region P2 into which the reaction gas that reacts with the precursor gas adsorbed on the substrate W in the precursor gas supply region P1 is supplied to form a molecular layer of the reaction product. The molecular layer of the reaction product constitutes a film to be deposited. A region below the process gas nozzle 32 serves as a modifying region P3 in which the modifying gas is supplied to the reaction product (film) generated in the reaction gas supply region P2 to modify the film.

A plasma generator 80 is provided above the modifying region P3. The plasma generator 80 generates plasma from the modifying gas discharged from the process gas nozzle 32.

Two convex portions 4 are provided in the vacuum container 1. In order to constitute an isolation region D together with the isolation gas nozzles 41 and 42, the convex portions 4 is attached to the rear surface of the ceiling plate 11 to protrude toward the rotary table 2. Each of the convex portions 4 has a fan-shaped planar shape with its top portion cut into an arc shape. The convex portions 4 are arranged such that the inner arc is connected to a protruding portion 5, which will be described later, and the outer arc is in conformity with the inner peripheral surface of the container body 12 of the vacuum container 1.

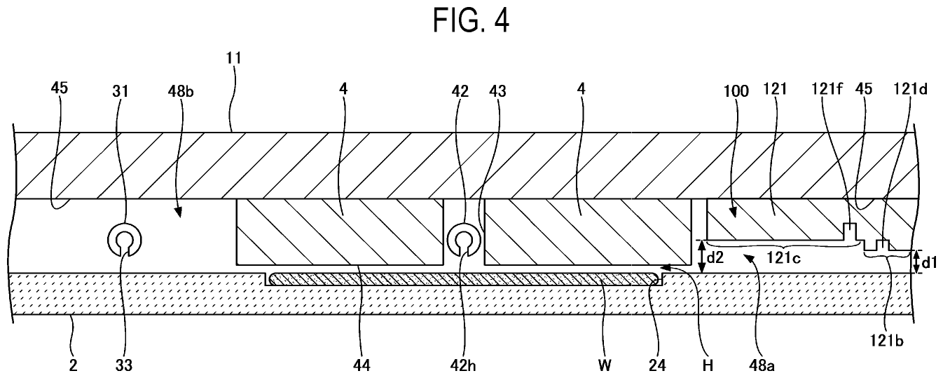

FIG. 4 shows a cross section of the vacuum container 1 along the concentric circle of the rotary table 2 from the bottom plate 121 of the shower head 100 to the process gas nozzles 31. As shown, the convex portions 4 are attached to the rear surface of the ceiling plate 11. Therefore, in the vacuum container 1, there are a first ceiling surface 44 that is a flat and lower ceiling surface which is the lower surface of the convex portion 4, and a second ceiling surface 45 that is located on both sides in the circumferential direction of the first ceiling surface 44 and is higher than the first ceiling surface 44. The first ceiling surface 44 has a fan-shaped planar shape with its top portion cut into an arc shape. A groove 43 formed to extend in the radial direction is formed in the center of the convex portion 4 in the circumferential direction. The isolation gas nozzle 42 is accommodated in the groove 43. The groove 43 is formed in the other convex portion 4 in the same manner, and the isolation gas nozzle 41 is accommodated therein. The bottom plate 121 and the process gas nozzle 31 are provided in a space below the second ceiling surface 45. The process gas nozzle 31 is provided near the substrate W away from the second ceiling surface 45. The bottom plate 121 is provided in a right space 48a below the second ceiling surface 45, and the process gas nozzle 31 is provided in a left space 48b below the second ceiling surface 45.

In the isolation gas nozzle 42 accommodated in the groove 43 of the convex portion 4, a plurality of discharge holes 42h opened toward the rotary table 2 are arranged at intervals of, for example, 10 mm, along the lengthwise direction of the isolation gas nozzle 42. Similarly to the isolation gas nozzle 42, also in the isolation gas nozzle 41 accommodated in the groove 43 of the convex portion 4, a plurality of discharge holes opened toward the rotary table 2 are arranged at intervals of, for example, 10 mm, along the lengthwise direction of the isolation gas nozzle 41.

The precursor gas supply 121d is provided at substantially the same height as the discharge holes 33 of the process gas nozzle 31 and the discharge holes 42h of the isolation gas nozzle 42. The outer auxiliary gas supply 121f is provided at a position higher than the precursor gas supply 121d. That is, the bottom plate 121 has a lower bottom region 121b and an upper bottom region 121c, the precursor gas supply 121d is provided in the lower bottom region 121b, and the outer auxiliary gas supply 121f is provided in the upper bottom region 121c. Further, although not shown in FIG. 4, the shaft side auxiliary gas supply 121e is also provided in the upper bottom region 121c, like the outer auxiliary gas supply 121f. The shaft side auxiliary gas supply 121e and the outer auxiliary gas supply 121f are just auxiliary and for adjustment purposes. Accordingly, if the flow of the precursor gas supplied from the precursor gas supply 121d is hindered by them, the role of improving the in-plane uniformity in adsorption of the precursor gas cannot be achieved. That is, it is necessary to limit the influence to the extent that the flow of the precursor gas is not hindered, and therefore it is preferable that a distance to the surface of the substrate W is farther than the precursor gas supply 121d. Therefore, a distance d2 between the shaft side auxiliary gas supply 121e/the outer auxiliary gas supply 121f and the rotary table 2 is set to be longer than a distance d1 between the precursor gas supply 121d and the rotary table 2.

The first ceiling surface 44 forms a narrow isolation space H with respect to the rotary table 2. When the isolation gas is supplied from the discharge holes 42h of the isolation gas nozzle 42, the isolation gas flows through the isolation space H toward the spaces 48a and 48b. At this time, since the volume of the isolation space H is smaller than the volume of the spaces 48a and 48b, the isolation gas can make the pressure of the isolation space H higher than the pressure of the spaces 48a and 48b. That is, the isolation space H with high pressure is formed between the spaces 48a and 48b. Further, the isolation gas flowing out from the isolation space H to the spaces 48a and 48b acts as a counter flow against the precursor gas from the precursor gas supply region P1 and the reaction gas from the reaction gas supply region P2. Therefore, the precursor gas from the precursor gas supply region P1 and the reaction gas from the reaction gas supply region P2 are isolated from each other by the isolation space H. Therefore, mixing of the precursor gas and the reaction gas in the vacuum container 1 is suppressed.

The protruding portion 5 surrounding the outer periphery of the core portion 21 to which the rotary table 2 is fixed is provided on the lower surface of the ceiling plate 11. The protruding portion 5 is continuous with a portion of the convex portion 4 on the rotation center side, and the lower surface thereof is formed at the same height as the first ceiling surface 44.

FIG. 5 is a cross-sectional view showing a region where the first ceiling surface 44 is provided. As shown in FIG. 5, an L-shaped bent portion 46 is formed on the periphery of the fan-shaped convex portion 4 to face the outer end surface of the rotary table 2. Like the convex portion 4, the bent portion 46 suppresses the precursor gas and the reaction gas from entering from both sides of the isolation region D to suppress the mixing of the precursor gas and the reaction gas. Since the convex portion 4 is provided on the ceiling plate 11 and the ceiling plate 11 is configured such that it can be removed from the container body 12, there is a slight gap between the outer peripheral surface of the bent portion 46 and the container body 12. A gap between the inner peripheral surface of the bent portion 46 and the outer end surface of the rotary table 2 and the gap between the outer peripheral surface of the bent portion 46 and the container body 12 are set to the same dimensions as, for example, the height of the first ceiling surface 44 with respect to the upper surface of the rotary table 2.

In the isolation region D, the inner peripheral surface of the container body 12 is formed in a vertical plane close to the outer peripheral surface of the bent portion 46, as shown in FIG. 5. On the other hand, the inner peripheral surface of the container body 12 is concave in a portion other than the isolation region D outward from a portion facing the outer end surface of the rotary table 2 to the bottom 14, as shown in FIG. 1. Hereinafter, for convenience of description, a concave portion having substantially a rectangular cross-sectional shape will be referred to as an exhaust region. Specifically, an exhaust region communicating to the precursor gas supply region P1 is referred to as a first exhaust region E1, and a region communicating to the reaction gas supply region P2 and the modifying region P3 is referred to as a second exhaust region E2.

As shown in FIGS. 1 to 3, a first exhaust port 61 and a second exhaust port 62 are formed at the bottoms of the first exhaust region E1 and the second exhaust region E2, respectively. The first exhaust port 61 and the second exhaust port 62 are connected to a vacuum pump 64 via an exhaust pipe 63. An automatic pressure controller (APC) 65 is provided in the exhaust pipe 63.

A heater unit 7 is provided in a space between the rotary table 2 and the bottom 14 of the vacuum container 1. The heater unit 7 heats the substrate W on the rotary table 2 via the rotary table 2. An annular cover member 71 is provided below the rotary table 2 in the vicinity of its periphery. The cover member 71 separates the atmosphere from the upper space of the rotary table 2 to the exhaust regions E1 and E2 from the atmosphere in which the heater unit 7 is placed, to suppress the intrusion of a gas into the lower region of the rotary table 2. The cover member 71 includes an inner member 71a provided to face the outer edge of the rotary table 2 and the outer side of the outer edge from below, and an outer member 71b provided between the inner member 71a and the inner peripheral surface of the vacuum container 1. The outer member 71b is provided below the bent portion 46 formed in the outer edge of the convex portion 4 in the isolation region D in vicinity of the bent portion 46. The inner member 71a surrounds the heater unit 7 over the entire circumference at a space below the outer edge of the rotary table 2 (and below a portion slightly outside the outer edge).

The bottom 14 at a portion closer to the center of rotation than a space in which the heater unit 7 is placed protrudes upward to approach the core portion 21 near the center portion of the lower surface of the rotary table 2 to form a protruding portion 12a. A narrow space is formed between the protruding portion 12a and the core portion 21, and a gap between the inner peripheral surface of a through-hole for the rotary shaft 22 penetrating the bottom 14 and the rotary shaft 22 is narrow. This narrow space communicates to the case body 20. The case body 20 is provided with a purge gas supply pipe 72 for supplying a purge gas such as an argon gas into the narrow space for purging. A plurality of purge gas supply pipes 73 for purging the placement space of the heater unit 7 are provided at the bottom 14 of the vacuum container 1 at predetermined angular intervals in the circumferential direction below the heater unit 7. In order to prevent a gas from entering the region where the heater unit 7 is provided, a lid member 7a is provided between the heater unit 7 and the rotary table 2 to cover a region from the inner peripheral surface of the outer member 71b (the upper surface of the inner member 71a) to the upper end of the protruding portion 12a along the circumferential direction. The lid member 7a is made of, for example, quartz.

An isolation gas supply pipe 51 is connected to the central portion of the ceiling plate 11 of the vacuum container 1. The isolation gas supply pipe 51 supplies an isolation gas such as an argon gas into a space 52 between the ceiling plate 11 and the core portion 21. The isolation gas supplied into the space 52 is discharged toward the periphery along the surface of the rotary table 2 on a wafer placing region side through a narrow gap 50 between the protruding portion 5 and the rotary table 2. The gap 50 may be maintained at a higher pressure than the spaces 48a and 48b by the isolation gas. Therefore, the gap 50 prevents the precursor gas supplied into the precursor gas supply region P1 and the reaction gas supplied into the reaction gas supply region P2 from passing through a central region C and mixing with each other. That is, the gap 50 (or the central region C) functions similarly to the isolation space H (or the isolation region D).

Thus, the isolation gas is supplied from the isolation gas supply pipe 51 to the shaft side of the rotary table 2 and the purge gas is supplied from the purge gas supply pipe 72 to the shaft side of the rotary table 2.

The transfer port 15 for transferring the substrate W between a transfer arm 10 and the rotary table 2 is formed in a sidewall of the vacuum container 1. The transfer port 15 is configured to be capable of being air-tightly opened/closed by a gate valve (not shown). The substrate W placed in the concave portion 24 of the rotary table 2 is delivered to/from the transfer arm 10 at a position facing the transfer port 15.

The substrate processing apparatus has a controller 90. The controller 90 is, for example, a computer and controls the operation of the entire apparatus. A memory of the controller 90 stores a program for causing the substrate processing apparatus to process the substrate. The program includes step groups to execute various operations of the apparatus and is stored in a recording medium 92. The program is read into a storage part 91 by a predetermined reading device and is installed in the controller 90. The recording medium 92 is a non-transitory computer-readable storage medium, for example, a flash memory, a hard disk, a compact disc, a magneto-optical disc, a memory card, or a flexible disk.

### [Shower Head]

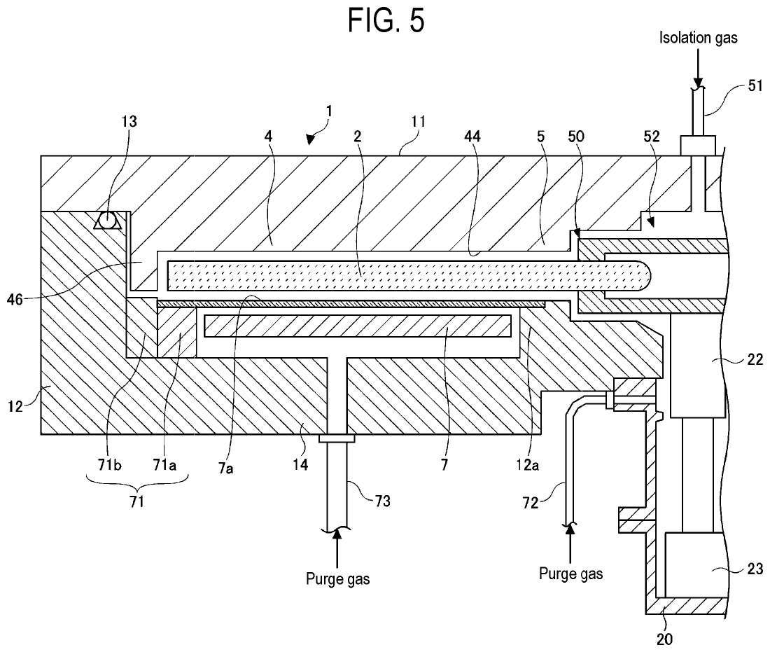

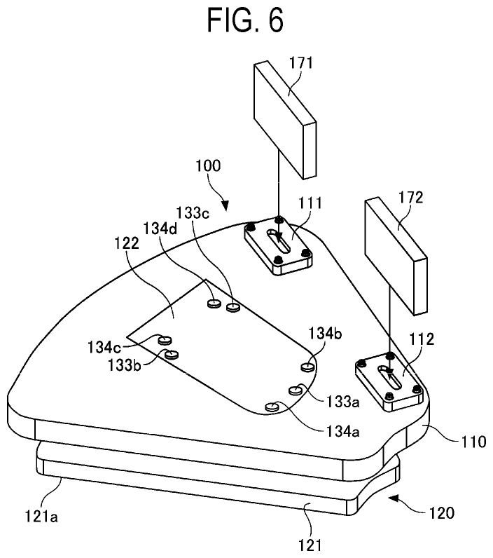

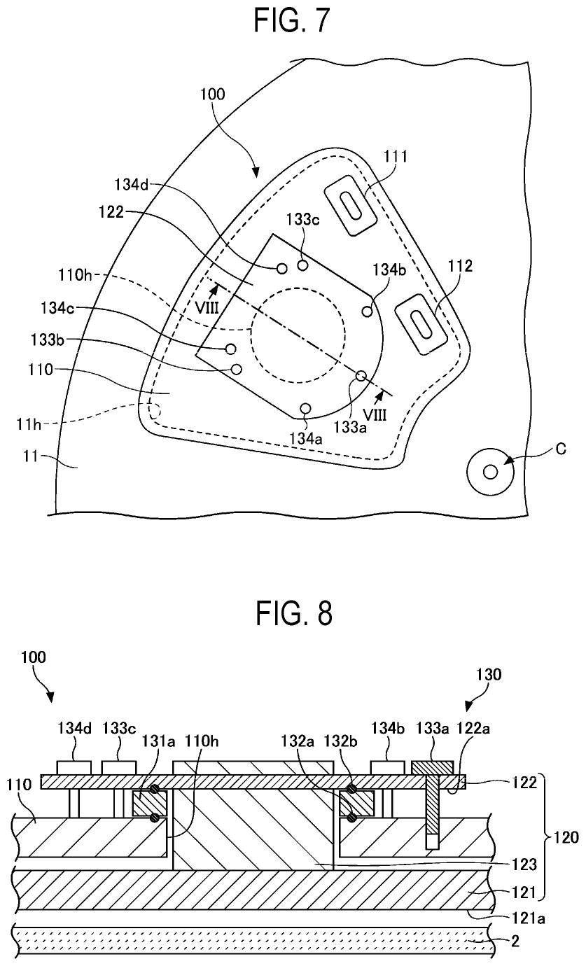

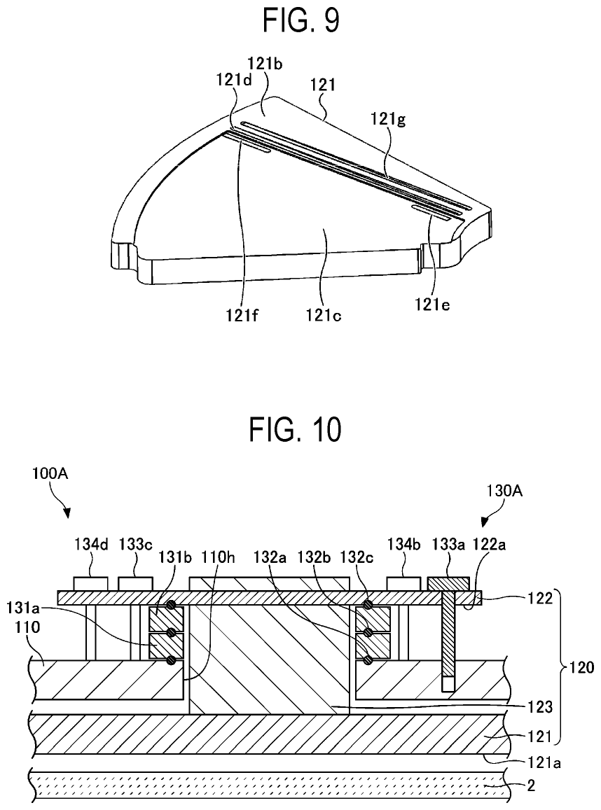

The shower head 100 provided in the substrate processing apparatus according to the embodiment will be described with reference to FIGS. 6 to 9. FIG. 6 is a schematic perspective view showing the shower head 100 according to the embodiment. FIG. 7 is a schematic plan view showing the shower head 100 according to the embodiment. FIG. 8 is a schematic cross-sectional view showing the shower head 100 according to the embodiment, taken along line VIII-VIII in FIG. 7. FIG. 9 is a view showing a configuration of the lower surface of the bottom plate 121 of the shower head 100 according to the embodiment.

The shower head 100 has a fixed member 110, a movable member 120, and an adjustment mechanism 130.

The fixed member 110 has substantially a fan shape centered on a central region C side in a plan view from the vertical direction. The fixed member 110 is air-tightly attached to an opening 11h formed in the ceiling plate 11. The opening 11h has substantially a fan shape centered on the central region C side in a plan view from the vertical direction. The fixed member 110 has an opening 110h. The opening 110h has substantially a cylindrical shape. The opening 110h is positioned substantially at the center of the rotary table 2 in the radial direction and the circumferential direction in a plan view from the vertical direction. The fixed member 110 is made of, for example, a metal material such as aluminum.

The fixed member 110 is provided with two windows 111 and 112. The window 111 is provided radially outside the rotary table 2 on the downstream side in the rotational direction of the rotary table 2. The window 112 is provided radially inside the rotary table 2 on the downstream side in the rotational direction of the rotary table 2. The windows 111 and 112 are provided with, for example, quartz glass so that the placing surface of the rotary table 2 inside the vacuum container 1 can be visually recognized from the outside thereof.

A laser displacement gauge 171 is provided above the window 111. That is, the laser displacement gauge 171 is provided radially outside the rotary table 2. The laser displacement gauge 171 measures the height positions of the upper surface of the rotary table 2, the upper surface of the substrate W, the upper surface of the bottom plate 121 to be described later, and the like on the radially outer side of the rotary table 2 through the window 111.

A laser displacement gauge 172 is provided above the window 112. That is, the laser displacement gauge 172 is provided radially inside the rotary table 2. The laser displacement gauge 172 measures the height positions of the upper surface of the rotary table 2, the upper surface of the substrate W, the upper surface of the bottom plate 121 to described later, and the like, on the radially inner side of the rotary table 2 through the window 112.

The laser displacement gauges 171 and 172 transmit measured values to the controller 90. Based on the measured values of the laser displacement gauges 171 and 172, the controller 90 calculates a first distance between the placing surface on the outer side of the rotary table 2 and the facing surface 121a to be described later, and a second distance between the placing surface on the inner side of the rotary table 2 and the facing surface 121a. The controller 90 calculates an inclination of the bottom plate 121 with respect to the placing surface in the radial direction of the rotary table 2 based on the first distance and the second distance. The laser displacement gauges 171 and 172 are, for example, two-dimensional laser displacement gauges.

The number of windows is not limited to two. For example, a window may be provided in the center of the rotary table 2 in the radial direction on the downstream side of the rotary table 2 in the rotational direction. That is, the window may be provided between the window 111 and the window 112. In this case, since the inclination of the bottom plate 121 with respect to the placing surface can be calculated at three points in the radial direction of the rotary table 2, the accuracy of inclination measurement is improved. Further, a window may be provided on the upstream side in the rotational direction of the rotary table 2. In this case, the inclination of the facing surface 121a with respect to the placing surface in the rotational direction of the rotary table 2 can be calculated.

The movable member 120 has the bottom plate 121, a ceiling plate 122, and a connecting portion 123. The bottom plate 121, the ceiling plate 122, and the connecting portion 123 are made of, for example, a metal material such as aluminum. The bottom plate 121, the ceiling plate 122, and the connecting portion 123 are formed separately in the shown example, but may be integrally formed.

The bottom plate 121 is provided below the lower surface of the fixed member 110 with a gap from the lower surface of the fixed member 110. The bottom plate 121 has substantially a fan shape centered on the central region C side in a plan view from the vertical direction. The bottom plate 121 has the facing surface 121a that faces the upper surface (the placing surface) of the rotary table 2. The facing surface 121a includes a lower bottom region 121b and an upper bottom region 121c (see FIG. 9). The precursor gas supply 121d is provided in the lower bottom region 121b. The shaft side auxiliary gas supply 121e and the outer auxiliary gas supply 121f are provided in the upper bottom region 121c. The lower bottom region 121b is provided on the upstream side in the rotational direction of the rotary table 2. The precursor gas supply 121d, the shaft side auxiliary gas supply 121e, and the outer auxiliary gas supply 121f are provided on the upstream side in the rotational direction of the rotary table 2 from the symmetrical center of the fan shape in the rotational direction. The shaft side auxiliary gas supply 121e and the outer auxiliary gas supply 121f are provided near the precursor gas supply 121d and are provided at positions where the concentration of the precursor gas supplied from the precursor gas supply 121d can be adjusted. A cleaning gas supply 121g is provided on the upstream side of the precursor gas supply 121d in the lower bottom region 121b. The cleaning gas supply 121g supplies a cleaning gas when cleaning the interior of the vacuum container 1. The cleaning gas supply 121g may not be provided.

The ceiling plate 122 is provided above the upper surface of the fixed member 110 with a gap from the upper surface of the fixed member 110. The ceiling plate 122 is provided in parallel to the bottom plate 121. The ceiling plate 122 has a shape that is larger than the opening 110h and smaller than the external shape of the fixed member 110 in a plan view from the vertical direction. The ceiling plate 122 has a facing surface 122a that faces the upper surface of the fixed member 110.

The connecting portion 123 has substantially a cylindrical shape. The connecting portion 123 has an outer diameter slightly smaller than the inner diameter of the opening 110h. The connecting portion 123 is inserted through the opening 110h. The connecting portion 123 connects the bottom plate 121 and the ceiling plate 122.

The adjustment mechanism 130 has a spacer 131a, seal members 132a and 132b, adjustment bolts 133a to 133c, and fixing bolts 134a to 134d.

The spacer 131a is sandwiched between the upper surface of the fixed member 110 and the facing surface 122a of the ceiling plate 122. The spacer 131a has an annular plate shape with an inner diameter larger than the inner diameter of the opening 110h and is provided around the connecting portion 123. The spacer 131a is made of, for example, a metal material such as aluminum.

The seal member 132a is provided between the upper surface of the fixed member 110 and the lower surface of the spacer 131a. The seal member 132a seals a gap between the fixed member 110 and the spacer 131a. The seal member 132a is formed of, for example, an elastic resin component. The seal member 132a is, for example, an O-ring.

The seal member 132b is provided between the facing surface 122a of the ceiling plate 122 and the upper surface of the spacer 131a. The seal member 132b seals a gap between the ceiling plate 122 and the spacer 131a. The seal member 132b is formed of, for example, the same component as the seal member 132a.

The adjustment bolts 133a to 133c are screwed into the fixed member 110 through the ceiling plate 122 from above. The adjustment bolt 133a is provided at a position closer to the central region C than the connecting portion 123 in the radial direction of the rotary table 2. The adjustment bolts 133b and 133c are provided at positions farther from the central region C than the connecting portion 123 in the radial direction of the rotary table 2. The adjustment bolts 133b and 133c are provided at positions equidistant from the center of the rotary table 2. The adjustment bolt 133b is provided on the upstream side of the adjustment bolt 133c in the rotational direction of the rotary table 2. Note that the number of adjustment bolts is not limited to three, and may be, for example, two or four or more.

The adjustment bolts 133a to 133c are configured to change the compression rate of the seal members 132a and 132b to adjust the vertical position and inclination of the movable member 120 with respect to the fixed member 110 by adjusting at least one screwing amount. The screwing amounts of the adjustment bolts 133a to 133c are set within a range in which the compression rate of the seal members 132a and 132b does not lead to vacuum breakage. The screwing amounts of the adjustment bolts 133a to 133c are set so that the compression rate of the seal members 132a and 132b is within a range of 10% or more and 25% or less.

For example, when all the adjustment bolts 133a to 133c are tightened, the movable member 120 moves downward with respect to the fixed member 110. As a result, a gap between the upper surface of the rotary table 2 and the facing surface 121a of the bottom plate 121 is narrowed. On the other hand, when all the adjustment bolts 133a to 133c are loosened, the movable member 120 moves upward with respect to the fixed member 110. As a result, the gap between the upper surface of the rotary table 2 and the facing surface 121a of the bottom plate 121 is widened. By tightening or loosening all the adjustment bolts 133a to 133c in this manner, the gap between the upper surface of the rotary table 2 and the facing surface 121a of the bottom plate 121 can be adjusted.

For example, when the adjustment bolt 133a is tightened while the adjustment bolts 133b and 133c are fixed, the inner side of the movable member 120 moves downward with respect to the fixed member 110. As a result, a distance between the upper surface of the rotary table 2 and the facing surface 121a of the bottom plate 121 is narrowed in the inner side of the movable member 120. When the adjustment bolt 133a is tightened, the adjustment bolts 133b and 133c may be loosened. On the other hand, when the adjustment bolts 133b and 133c are tightened while the adjustment bolt 133a is fixed, the outer side of the movable member 120 moves downward with respect to the fixed member 110. As a result, the distance between the upper surface of the rotary table 2 and the facing surface 121a of the bottom plate 121 is narrowed in the outer side of the movable member 120. When the adjustment bolts 133b and 133c are tightened, the adjustment bolt 133a may be loosened. By tightening or loosening one or more of the adjustment bolts 133a to 133c in this way, variations in the gap between the upper surface of the rotary table 2 and the facing surface 121a of the bottom plate 121 can be adjusted.

In addition, a dial gauge may be arranged in order to tighten the adjustment bolt 133b and the adjustment bolt 133c to the same degree.

The fixing bolts 134a to 134d are screwed into the fixed member 110 through the ceiling plate 122 from above. The fixing bolts 134a and 134b are provided at positions closer to the central region C than the connecting portion 123 in the radial direction of the rotary table 2. The fixing bolts 134 c and 134d are provided at positions farther from the central region C than the connecting portion 123 in the radial direction of the rotary table 2. The fixing bolts 134a and 134b are provided at positions equidistant from the center of the rotary table 2. The fixing bolt 134a is provided on the upstream side of the fixing bolt 134b in the rotational direction of the rotary table 2. The fixing bolts 134c and 134d are provided at positions equidistant from the center of the rotary table 2. The fixing bolt 134c is provided on the upstream side of the fixing bolt 134d in the rotational direction of the rotary table 2. The fixing bolts 134a to 134d are provided to prevent vacuum breakage due to excessive loosening of the adjustment bolts 133a to 133c. Note that the number of fixing bolts is not limited to four, and may be, for example, two or three, or may be five or more. Moreover, the fixing bolts may not be provided.

The shower head 100 described above includes the spacer 131a and the seal members 132a and 132b sandwiched between the fixed member 110 and the ceiling plate 122, and the adjustment bolts 133a to 133c screwed into the fixed member 110 through the ceiling plate 122. As a result, by tightening or loosening the adjustment bolts 133a to 133c, the compression rate of the seal members 132a and 132b can be changed to adjust the vertical position and inclination of the movable member 120 with respect to the fixed member 110. Therefore, the gap between the upper surface of the rotary table 2 and the facing surface 121a of the bottom plate 121 can be adjusted while the interior of the vacuum container 1 is maintained in a reduced pressure atmosphere or an elevated temperature atmosphere. As a result, the time required for the work of adjusting the gap can be shortened.

Further, according to the shower head 100, the spacer 131a and the seal members 132a and 132b are used in place of a bellows in order to ensure the airtightness of the interior of the vacuum chamber 1. As a result, the configuration of the adjustment mechanism 130 is simplified, and reaction products are less likely to deposit on the adjustment mechanism 130 when a process of depositing a film on the substrate W is performed in the substrate processing apparatus. Therefore, it is possible to suppress the generation of particles accompanying the separation of reaction products.

A modification of the shower head 100 provided in the substrate processing apparatus according to the embodiment will be described with reference to FIG. 10. FIG. 10 is a schematic cross-sectional view showing a shower head 100A according to a modification of the embodiment.

The shower head 100A is different from the shower head 100 in that two spacers 131a and 131b are stacked in a direction perpendicular to the facing surface 121a. Other configurations may be substantially the same as those of the shower head 100. The configuration different from the shower head 100 will be mainly described below.

The shower head 100A has a fixed member 110, a movable member 120, and an adjustment mechanism 130A.

The adjustment mechanism 130A has spacers 131a and 131b, seal members 132a to 132c, adjustment bolts 133a to 133c, and fixing bolts 134a to 134d.

The spacers 131a and 131b are sandwiched between the upper surface of the fixed member 110 and the facing surface 122a of the ceiling plate 122. The spacers 131a and 131b have an annular plate shape with an inner diameter larger than the inner diameter of the opening 110h and are provided around the connecting portion 123. The spacers 131a and 131b are stacked in this order from the fixed member 110 side. The spacers 131a and 131b are made of, for example, a metal material such as aluminum.

The seal member 132a is provided between the upper surface of the fixed member 110 and the lower surface of the spacer 131a. The seal member 132a seals a gap between the fixed member 110 and the spacer 131a. The seal member 132a is formed of, for example, an elastic resin component. The seal member 132a is, for example, an O-ring.

The seal member 132b is provided between the upper surface of the spacer 131a and the lower surface of the spacer 131b. The seal member 132b seals a gap between the spacer 131a and the spacer 131b. The seal member 132b is formed of, for example, the same component as the seal member 132a.

The seal member 132c is provided between the facing surface 122a of the ceiling plate 122 and the upper surface of the spacer 131b. The seal member 132c seals a gap between the ceiling plate 122 and the spacer 131b. The seal member 132c is formed of, for example, the same component as the seal member 132a.

The shower head 100A described above includes the spacers 131a and 131b and the seal members 132a to 132c sandwiched between the fixed member 110 and the ceiling plate 122, and the adjustment bolts 133a to 133c screwed into the fixed member 110 through the ceiling plate 122. As a result, by tightening or loosening the adjustment bolts 133a to 133c, the compression rate of the seal members 132a to 132c can be changed to adjust the vertical position and inclination of the movable member 120 with respect to the fixed member 110. Therefore, the gap between the upper surface of the rotary table 2 and the facing surface 121a of the bottom plate 121 can be adjusted while the interior of the vacuum container 1 is maintained in a reduced pressure atmosphere or an elevated temperature atmosphere. As a result, the time required for the work of adjusting the gap can be shortened.

Further, according to the shower head 100A, the spacers 131a and 131b and the seal members 132a to 132c are used in place of a bellows in order to ensure the airtightness of the interior of the vacuum chamber 1. As a result, the configuration of the adjustment mechanism 130A is simplified, and reaction products are less likely to deposit on the adjustment mechanism 130A when a process of depositing a film on the substrate W is performed in the substrate processing apparatus. Therefore, it is possible to suppress the generation of particles accompanying the separation of reaction products.

In particular, according to the shower head 100A, since three seal members 132a to 132c are provided between the fixed member 110 and the ceiling plate 122, the adjustment range of the vertical position and inclination of the movable member 120 with respect to the fixed member 110 can be expanded.

It should be considered that the embodiments disclosed herein are illustrative in all respects and not restrictive. The above-described embodiments may be omitted, substituted, or changed in various ways without departing from the appended claims and the gist thereof.

In the above-described embodiments, a case of adjusting the gap between the rotary table 2 and the shower head 100 has been described, but the present disclosure is not limited thereto. For example, a gap between the rotary table 2 and another ceiling member such as the convex portion 4 may be adjusted. In this case, the another ceiling member may be configured to have a fixed member, a movable member, and an adjustment mechanism.

In the above-described embodiments, as the substrate processing apparatus, an apparatus in which a plurality of substrates are placed along the circumferential direction of the rotary table and the substrates W are revolved by rotating the rotary table has been described, but the present disclosure is not limited thereto. For example, the substrate processing apparatus may be an apparatus in which a plurality of placing parts for placing the substrates along the circumferential direction of the rotary table 2 and the substrates W are rotated by rotating the placing parts with respect to the rotary table 2 while revolving the substrates W by the rotation of the rotary table 2.

According to the present disclosure in some embodiments, it is possible to adjust a gap between a ceiling member and a substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus comprising:
a vacuum container;
a placing part provided inside the vacuum container and having a placing surface on which a substrate is placed; and
a ceiling member provided above the placing part,
wherein the ceiling member comprises:
a fixed member fixed to the vacuum container;
a movable member attached to the fixed member and having a first facing surface facing the placing surface;
a spacer sandwiched between the fixed member and the movable member;
a first seal member provided between the fixed member and the spacer;
a second seal member provided between the movable member and the spacer; and
a plurality of adjustment bolts screwed into the fixed member through the movable member.

2. The substrate processing apparatus of claim 1, wherein the movable member includes:
a bottom plate including the first facing surface; and
a ceiling plate provided above the bottom plate and having a second facing surface facing an upper surface of the fixed member,
wherein the spacer is sandwiched between the upper surface of the fixed member and the second facing surface.

3. The substrate processing apparatus of claim 2, wherein a plurality of spacers are provided along a direction perpendicular to the first facing surface.

4. The substrate processing apparatus of claim 3, wherein the placing part includes a rotary table that is rotatably provided and places a plurality of substrates along a circumferential direction, and
wherein the plurality of adjustment bolts include two or more adjustment bolts provided at different positions in a radial direction of the rotary table.

5. The substrate processing apparatus of claim 4, wherein the ceiling member is a shower head that injects a gas into the vacuum container.

6. The substrate processing apparatus of claim 5, wherein the ceiling member has a window through which the placing surface can be viewed from above the ceiling member, and
a laser displacement gauge that is provided above the window and measures a height position of the movable member.

7. The substrate processing apparatus of claim 1, wherein a plurality of spacers are provided along a direction perpendicular to the first facing surface.

8. The substrate processing apparatus of claim 1, wherein the placing part includes a rotary table that is rotatably provided and places a plurality of substrates along a circumferential direction, and
wherein the plurality of adjustment bolts include two or more adjustment bolts provided at different positions in a radial direction of the rotary table.

9. The substrate processing apparatus of claim 1, wherein the ceiling member is a shower head that injects a gas into the vacuum container.

10. The substrate processing apparatus of claim 1, wherein the ceiling member has a window through which the placing surface can be viewed from above the ceiling member, and
a laser displacement gauge that is provided above the window and measures a height position of the movable member.
